(19) United States
(12) Patent Application Publication
(10) Pub. No.: US 2003/0228755 A1
(43) Pub. Date: Dec. 11, 2003

(54) Method for metal patterning and improved linewidth control

(76) Inventors: Thomas Craig Esry, Orlando, FL (US); John Martin McIntosh, Orlando, FL (US); Simon John Molloy, Allentown, PA (US); Mario Pita, Winter Springs, FL (US); Nace Layadi, Singapore (SG)

Correspondence Address: BEUSSE, BROWNLEE, BOWDOIN & WOLTER, P. A., 390 NORTH ORANGE AVENUE, SUITE 2500, ORLANDO, FL, 32801, US

(21) Appl. No.: 10/165,845

(22) Filed: Jun. 7, 2002

(51) Int. Cl. H01L 21/44

(52) U.S. Cl. 438/669

(57) ABSTRACT

Method for forming metal lines during the fabrication of an integrated circuit including the step of stripping a photoresist layer to expose a patterned antireflective coating layer prior to performing a metal etch. A semiconductor substrate is prepared with a metal layer for the formation of metal lines. The photoresist is exposed and developed after being deposited on an antireflective coating that has been deposited on a composite metal stack. The method includes etching the antireflective coating, stripping the photoresist, etching a composite metal stack to form the metal lines, removing the antireflective coating and cleaning the metal stack. A device at this stage of manufacture is also disclosed.

### FIELD OF THE INVENTION

This invention relates to the manufacture of highly integrated circuits and more particularly to a method for metal patterning with improved linewidth control.

### BACKGROUND OF THE INVENTION

The manufacture of highly integrated circuits requires the fabrication of a number of metal containing layers to interconnect various devices and components. With sub-micron technologies there can be up to six or more of such layers formed on a semiconductor substrate, which minimizes device access times and achieves lower electrical resistance that is caused by the length of the metal runners. These layers are typically patterned using a photoresist mask having a pattern defined by deep ultra-violet (“DUV”) radiation exposure and subsequent development. By way of example, prior to the metal patterning steps, typically the photoresist layer may be exposed to DUV radiation using a conventional krypton-fluoride laser at a standard DUV wavelength of 248 nanometers. The subsequent development step results in the exposed areas of the photoresist being rinsed away while leaving the unexposed features that form the photoresist mask to be used for the metal patterning. Other types of radiation may be used and either positive or negative patterns may be developed by processes known in the art.

Various composite structures may be used in conjunction with the photoresist mask during the formation of an integrated circuit. One common structure is a composite formed of Titanium Nitride/Aluminum/Titanium Nitride/Titanium (“TiN/Al/TiN/Ti”), which may be deposited on a substrate by conventional techniques in a multi-chamber reactor as part of the integrated circuit fabrication process. Such composites may be referred to herein as a “metal stack”. The thickness of the individual layers of the metal stack may vary with the aluminum layer typically being the thickest. The aluminum may be alloyed with copper and/or silicon, with copper being used as the primary metal in the latest integrated circuit designs.

Typically, the metal stack is formed by first depositing a layer of titanium on the substrate. This layer acts as an adhesion layer between the substrate and the metal stack. A first layer of titanium nitride is then deposited on the titanium. This layer acts as a diffusion barrier between a layer of aluminum and the silicon of the substrate. The layer of aluminum, which serves as the primary current carrying metal in the finished integrated circuit, is then deposited on the titanium nitride. A second layer of titanium nitride is deposited on the aluminum serving as a diffusion barrier and capping layer on which an inorganic antireflective coating (“ARC”) is subsequently deposited. Each layer of the metal stack may be deposited to varying depths as a function of the integrated circuit design and performance specifications.

It is known that the capping layer of titanium nitride possesses some level of antireflective properties, which may protect the photoresist mask against reflective notching and other adversities during its exposure to ultra-violet radiation; however, optimal control of DUV lithography requires additional protection against these adverse effects. Thus, an anti-reflective coating is frequently used in addition to the upper layer of TiN during lithography to minimize reflective notching and other potentially adverse consequences to the pattern integrity of the photoresist mask. A common combination for metal patterning known in the art includes a photoresist mask on top of an ARC that has been deposited on the metal stack. The ARC may be deposited using a conventional plasma enhanced CVD system.

After exposing and developing the photoresist to form a mask, conventional methods of metal patterning include first etching the ARC and then etching the full metal stack in a single reactor with the photoresist serving as the metal patterning mask. Typically, a first fluorinated gas chemistry such as CF₄ and O₂, C₂F₆ and O₂, Cl and O₂ or others known in the art may be used to etch the ARC. The gas chemistry is then changed to etch the metal stack. Subsequent to etching the ARC and metal stack it is necessary to remove the photoresist mask. An O₂ based plasma photoresist strip is typically performed and then an H₂O vapor plasma step for passivation is conducted followed by a rinse in deionized water. Known techniques will sometimes alternate between the O₂ plasma strip and the H₂O vapor plasma step before rinsing. Some residue materials will remain on the sidewalls of the metal after the strip and passivation step. Rinsing will remove water-soluble residue such as Cl, for example. The passivation step helps prevent corrosion of the metals. A subsequent Na+ removal etch or solvent clean may be performed to remove the sidewall residues and mobile ion contamination.

One problem associated with conventional methods of metal patterning is that the width of isolated lines or features tend to grow more during the metal etch than does the width of more closely spaced lines or features due to polymers in the plasma and byproducts from the etch reaction that tend to build up on any vertical wall, especially those isolated from others. The photoresist mask is a large source of carbon that forms the polymers and byproducts during the metal etch reaction. Some polymer formation is desirable during the etch to inhibit notching of the sidewalls and other features due to the presence of Cl during the reaction. However, such growth may result in an etch bias between isolated lines and those lines or features that are more closely nestled together, which may result in a degradation in performance of the finished integrated circuit. Also, with conventional metal etching techniques, the polymer is frequently heavier than needed for passivation, which may cause an unwanted tapered profile to the metal lines. While some polymer is removed during the photoresist strip, complete removal of the remaining polymer usually requires an O₂ plasma and a subsequent solvent clean. It is generally known that polymer removal is made more difficult by O₂ plasma alone because Al and Ti become incorporated in the sidewalls during the metal etch. Thus, the heavier the polymer, the more difficult and costly it is to remove.

As technologies migrate to smaller sizes, selectivity of the etch process presents difficult technological challenges. Selectivity is a measure of how fast the photoresist will etch compared to the target metal being etched. In order to meet the demands of smaller sizes, the photoresist must be thinner to achieve the needed resolution. Demands for thinner photoresists limit the options available for metal etch process developments. For example, with known methods it is desirable to stay above a certain level of photoresist selectivity. This limits the use of certain combinations of gases during the metal etch because those combinations would erode or consume most or all of the photoresist prematurely. It is known in the art that CHF₃ may be used to improve selectivity to the photoresist. However, a disadvantage of introducing CHF₃ to the metal etch environment is that more carbon is available for polymer formation in addition to the carbon originating from the photoresist. This may result in a heavier polymer than desired.

Another problem confronted by the industry is potential damage to the substrate resulting from a plasma etch. For example, plasma damage to a gate dielectric due to the effects of “electron shading” is a common problem with known metal patterning techniques. Electron shading refers to the voltage differences developed between the bottom and top of high aspect ratio structures being defined by the metal etch, such as the metal lines. The voltage differences are created due to differences in the trajectories of ions and electrons from the plasma. Electrons are “shaded” by high aspect ratio features and don't pass to the bottom of such a feature, which is the area where the titanium and titanium/nitride barrier layers are being cleared away by the etch. However, positively charged ions are not “shaded” and tend to accumulate near the bottom of the feature creating a potentially dangerous charge differential. For example, a sufficiently large charge differential may be created across a gate dielectric of a transistor on the substrate to destroy the dielectric, thereby adversely impacting device yield or degrading its performance leading to failures in the field.

Importantly, the amount or severity of plasma damage has been demonstrated to increase with the overall height of the metal stack, ARC and photoresist layer. This damage primarily occurs during the clearing of the titanium nitride/titanium barrier at the end of the metal etch. One technique known in the art to minimize such plasma damage is to use a hard mask such as SiO2, for example. Such a hard mask may be situated between a metal stack and an upper layer of ARC during the metal etch. It has been shown that plasma damage is significantly reduced when a hard mask such as SiO2 is used to pattern the metal instead of a photoresist mask; however, this adds steps to the metal patterning process. Further, the SiO2 is usually left on top of the metal after etching thereby increasing the overall height of the features. This makes it more difficult to cover the metal lines in the next dielectric deposition step.

In view of the above, it would advantageous to provide a method for metal patterning where linewidth control was improved, sidewall formations could be better controlled and readily removed, and plasma-induced damage was reduced.

### SUMMARY OF THE INVENTION

In one aspect of a method of the present invention, an ARC layer is used as the mask during the metal etching or patterning step for forming metal lines or other features during the fabrication of an integrated circuit rather than a photoresist mask. Using the ARC instead of the photoresist as a mask provides advantages over the prior art methods and does not require any additional deposition steps as is the case when using an oxide hard mask for metal patterning, for example.

In accordance with one aspect of the present invention, a substrate is provided that has been prepared for a metal etch for the formation of lines or features within at least one metal stack composite deposited on the substrate. Preparation of the substrate may be performed by conventional techniques known in the art. The metal stack composite may include a layer of titanium deposited on a dielectric of the substrate such as a layer of silicon oxide, for example. A first layer of titanium nitride may be deposited on the titanium with a layer of aluminum deposited on the first layer of titanium nitride. A second layer of titanium nitride may be deposited on the layer of aluminum. Preparation of the substrate may also include the deposition of an ARC layer and photoresist layer. The photoresist layer may be exposed and developed using conventional techniques known in the art. The various layers of the metal stack composite, the ARC layer and the photoresist layer may be deposited to depths as a function of the specific integrated circuit design, fabrication constraints or performance specifications.

In one embodiment, an inorganic ARC layer may be used such as a silicon rich oxy-nitride that can absorb light in the deep end of the spectrum, which is necessary during DUV exposure of the photoresist layer. Precursors such as SiH4 or N2O may be used during the deposition of the ARC. Varying the gas flow ratio of the precursors permits deposition of the ARC having desired properties such as the ability to absorb wavelengths in the desired range for patterning the photoresist, achieving a desired thickness and obtaining a uniform thickness, for example.

Subsequent to providing the substrate and forming a pattern in the photoresist mask, one embodiment of a method of the present invention may include the step of etching or patterning the ARC layer for use as a mask rather than the photoresist mask for the subsequent metal etch. The ARC may be patterned with a dielectric etch tool with either a mixture of CF₄ and O₂ or C₂F₆ and O₂. After etching the ARC, a photoresist strip is performed by using an O₂ based downstream plasma. Stripping the photoresist mask prior to etching the metal stack provides several advantages over prior art methods that etch the metal stack using the photoresist layer as the mask. For example, conventional photoresist materials act as a large source of carbon in the plasma during the metal etch. This contributes to the formation of polymers and byproducts during the etch that tend to collect-on any vertical walls such as the sidewalls of the lines or features being formed in the metal. The inventors have observed that isolated lines or features suffer from greater sidewall formations than lines or features that are more closely spaced to one another. This inhibits the ability to control linewidth, especially for smaller and smaller lines in the sub-micron environment. Not having the photoresist as a source of carbon in the plasma during the etch of the metal stack changes the nature and amount of sidewall formation during the etch permitting improved control of linewidth and passivation.

An exemplary embodiment of the present invention allows for improved control of the amount of carbon during the metal etch, which permits improved control over sidewall formation and consequently the linewidth. With conventional methods, the amount of carbon was fixed as a function of the photoresist material and could not be adequately controlled during the metal etch thereby permitting undesirable sidewall formations. Controlling the introduction of carbon during the metal etch provides a significant advantage over the prior art because polymer formation during the metal etch may be better controlled allowing for improved linewidth control. This allows for improved performance of the finished integrated circuit.

Subsequent to the photoresist strip, lines or features may be formed in the metal layer by etching. CHF₃ may be added to a conventional BCl₃/Cl₂ gas mixture for controlling the amount of carbon introduced into the environment of the metal etch. Alternatively, other gas mixtures may also be used with CHF₃ such as HBr/CL₂ or gaseous HCI, for example. Stripping the photoresist prior to the metal etch step provides greater flexibility in the selection of gases during the metal etch. This may permit further improvements in linewidth control for even smaller lines due to the further reduction in polymers that would otherwise tend to accumulate on sidewalls. Furthermore, testing conducted by the inventors has demonstrated that removing the photoresist prior to the metal etch may eliminate the need for a subsequent wet cleaning step for removing undesirable polymers. This may result from better control over the introduction of carbon during the metal etch, which allows for improved control over carbon-based polymer formation.

Another aspect of the present invention allows for subsequent wet or dry cleaning steps to remove undesirable polymers and the ARC. The wet cleaning step may use commercially available solvents, for example, for removing unwanted polymers. However, as pointed out above, testing to date indicates that this step may not be necessary according to one aspect of the present invention. In particular, the dry cleaning step may be a downstream NF₃ or CF₄ plasma, which will remove the ARC layer with a very fast etch rate. This plasma step may remove the undesirable polymers, which would eliminate the need for a subsequent solvent clean. The plasma step may also convert the metal into fluorides, such as AlF₃, which may be rinsed away along with mobile ions and any remaining polymers in a subsequent water rinse. With the ARC removed, a subsequent film of dielectric material may be deposited with no complications added to the subsequent via etch that may be needed for contacting with the metal layer.

Another advantage of the present invention is that stripping the photoresist layer prior to etching the metal stack removes the constraints necessary to maintain photoresist selectivity. In the absence of the photoresist layer, the selectivity to the ARC must still be maintained; however, the selectivity to ARC provides greater process flexibility than working with the photoresist layer.

Furthermore, it is known that plasma damage may result to the metal layer during known etching processes. Having stripped the photoresist prior to etching the metal stack lowers the effective aspect ratio of the lines and other features as they evolve during the etch. This results in less electron shading compared to performing the metal etch with the photoresist mask. This is a significant advantage over the prior art because the present invention may improve device yield and increase their reliability in the field thereby providing significant cost savings. Also, the present invention uses standard equipment and etch gases so that no additional capital investment is required to achieve the improved results.

### DESCRIPTION OF THE DRAWINGS

FIG. 1 illustrates exemplary steps of one embodiment of a method of the present invention;

FIG. 2 illustrates an exemplary cross-sectional view of a prior art substrate prepared for the formation of metal lines or other features; and

FIG. 3 illustrates a prior art method of preparing a substrate for metal etch;

FIG. 4 illustrates a partial cross-sectional view of a semiconductor device at a stage of manufacture prior to an etching step; and

FIG. 5 illustrates the semiconductor device of FIG. 4 after an etching step.

### DESCRIPTION OF THE INVENTION

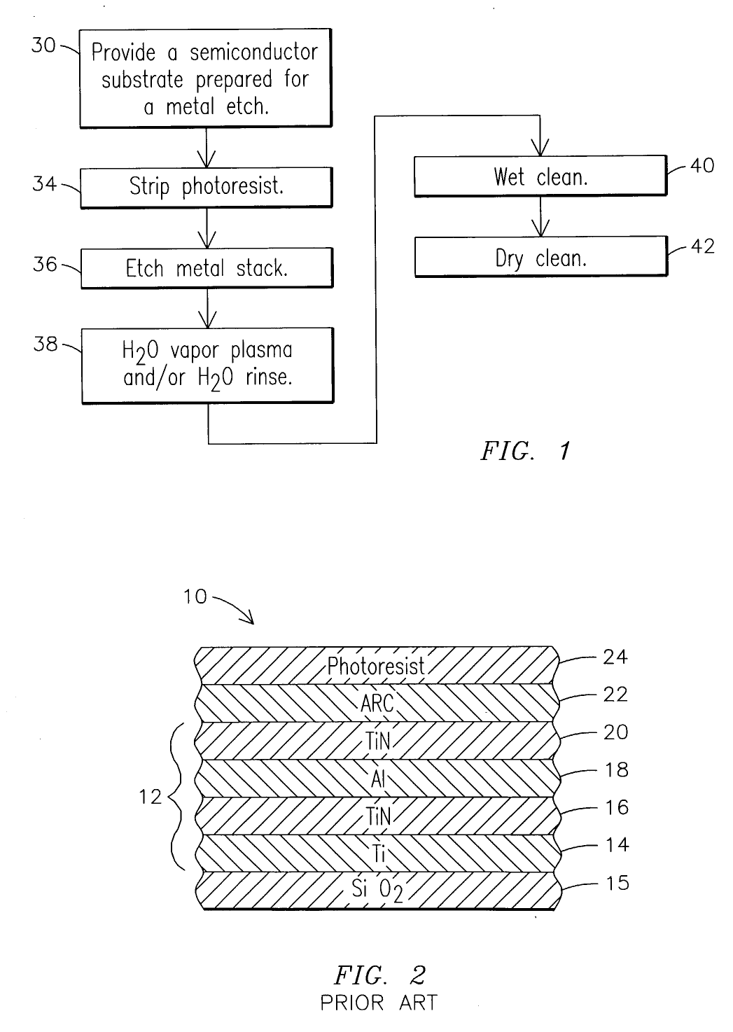

As illustrated in FIG. 1, one aspect of a method of the present invention includes the step 30 of providing a substrate 10, such as a substrate fabrication of semiconductor devices, for example, prepared for the formation of metal lines or other features within at least one metal stack composite. The metal stack composite generally referred to as 12, as shown in FIG. 2, may be comprised of a layer of titanium 14, which may be deposited on a dielectric layer 15 such as a silicon oxide, for example. The titanium layer 14 may be deposited to a depth of approximately 500 Angstroms. A first layer of titanium nitride 16 may be deposited to a depth of approximately 400-600 Angstroms on the layer of titanium 14, followed by a layer of aluminum 18 and a second layer of titanium nitride 20. The layer of aluminum 18 may be deposited to a depth of approximately 4,000-7,000 Angstroms and may be up to approximately 10,000 Angstroms deep. The second layer of titanium nitride 20 may be deposited to a depth of approximately 300-1,000 Angstroms. The composite metal stack composite 12 may be formed using conventional techniques. An antireflective coating (“ARC”) 22 is deposited on the metal stack composite 12 and a photoresist layer 24 is deposited on the ARC. The ARC may have been deposited using known techniques to a depth of approximately 750-800 Angstroms. Similarly, the photoresist layer 24 may be exposed and developed using conventional techniques. The individual layers of the substrate 10 may vary depending on integrated circuit design and fabrication parameters.

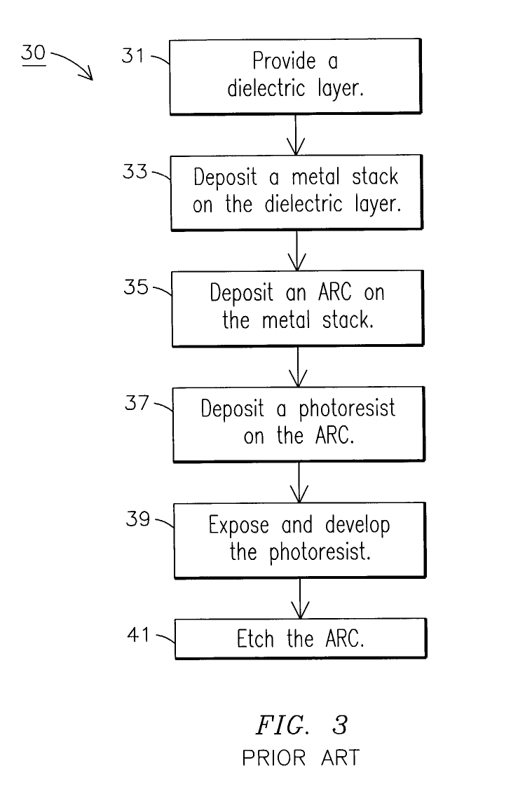

FIG. 3 illustrates the steps used to accomplish step 30 of FIG. 1 These may include step 31 of providing a dielectric layer 15 comprising an insulating material such as silicon dioxide, for example, step 33 of depositing a metal stack 12 on the dielectric layer 15, step 35 of depositing an ARC 22 on the metal stack 12, step 37 of depositing a photoresist 24 on the ARC 22, step 39 of exposing and developing the photoresist 24, and step 41 of etching the ARC. Each layer may be deposited using known techniques. One skilled in the art may appreciate that the layers illustrated in FIG. 2 are representative of layers disposed over other layers. Other intermediate layers may be disposed between such layers in other embodiments. The ARC may be etched using a dielectric etch tool or other similar means in step 41 to form a pattern using either a mixture of CF₄ and O₂ or C₂F₆ and O₂. Alternatively, the ARC may be etched in a metal etch reactor with a mixture of Cl₂, CHF₃, and O₂ or a mixture of Cl₂ and O₂. The ARC etching step 41 may leave the second layer of titanium nitride 20 intact. In one exemplary embodiment, the mixture for etching the ARC may be primarily CHF₃ with 10-15% or approximately 40-cc/min. of Cl₂, 30-cc/min. of CHF₃ and 8-10-cc/min. of O₂. Mixtures of Cl₂ and O₂ may have approximately 10-15% of the total flow being O₂.

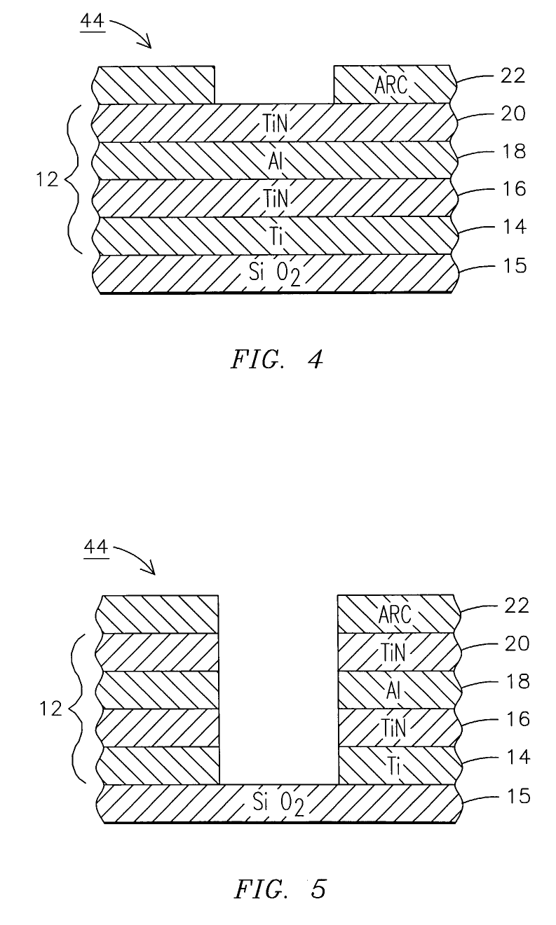

Referencing FIG. 1, subsequent to the step 30 of providing a substrate 10 prepared for metal etch, the photoresist mask may be stripped in step 34 by using a conventional O₂ based downstream plasma. The resulting device 44 is illustrated at this stage of manufacture in FIG. 4. With the photoresist 24 stripped, the ARC 22 is the only layer above the metal stack 12 and will expose at least a portion of the top surface of the metal layer 18 during the metal stack etch 36. Stripping the photoresist mask prior to etching the metal stack 12 provides the advantage of removing carbon from the subsequent metal stacketching step 36 due to photoresist compositions being a large source of carbon. Etching the metal stack 12 will form a pattern in the metal layer 18. The metal stack 12 may then be etched in step 36 using CHF₃, for example, which may be added to a BCl₃/Cl₂ gas mixture. This mixture provides the advantage of introducing carbon into the metal etching step 36 in a controlled manner and allows for the passivation to be better controlled. Thus, the metal stack etch may be controlled by adjusting the CHF₃ and BCl₃/Cl₂ gas mixture. Alternatively, other gas mixtures may be used with CHF₃ such as HBr/CL₂ or gaseous HCI, for example. Device 44 at this stage of manufacture is illustrated in FIG. 5. Step 38 allows for an H₂O vapor plasma and/or H₂O rinse, which will remove Cl from the sides of metal lines and other features to prevent corrosion of the exposed Al metal.

The composite metal stack 12 may then be cleaned using dry or wet methods. For example, in one embodiment of the present method, step 40 allows for a wet clean to be performed, if desired, using commercially available solvents to remove undesirable polymers. A dry clean may then be performed at step 42 such as a NF₃ or CF₄ plasma, for example, to remove the ARC and undesirable polymers. Step 42 may also convert the metal into fluorides such as A1F₃, which are rinsed away along with mobile ions, such as Na+ or K+, and any remaining polymers in a subsequent water rinse.

While the preferred embodiments of the present invention have been shown and described herein, it will be obvious that such embodiments are provided by way of example only. Numerous variations, changes and substitutions will occur to those of skill in the art without departing from the invention herein. Accordingly, it is intended that the invention be limited only by the spirit and scope of the appended claims.

We claim:

1. A method for forming a feature on a layer of metal, the method comprising the steps of:
providing a substrate prepared for a metal etch, the substrate comprising a metal layer, a patterned antireflective coating layer disposed on the metal layer and a patterned photoresist layer disposed on the antireflective coating layer;
stripping the photoresist layer; and
forming the feature on the metal layer through the patterned antireflective coating layer after stripping the photoresist layer.

2. The method of claim 1 further comprising:
controlling the step of forming the feature on the metal layer by adding a first gas mixture containing carbon to a second gas mixture selected from the group of BCl₃/Cl₂ and HBr/Cl₂ and gaseous HCL.

3. The method of claim 2, the first gas mixture comprising CHF₃.

4. The method of claim 3, the second gas mixture comprising BCl₃/Cl₂.

5. The method of claim 1 further comprising the step of:
cleaning the substrate using a gas plasma after forming the feature on the metal layer.

6. The method of claim 1, the step of providing the substrate comprising:
providing a layer containing titanium;
providing a first layer containing titanium nitride disposed on the titanium layer;
providing a layer containing aluminum disposed on the first titanium nitride layer; and
providing a second layer containing titanium nitride disposed on the aluminum layer.

7. A method for fabricating a device comprising the steps of:
providing a substrate;
disposing a metal layer over the substrate;
depositing an antireflective coating on the metal layer;
depositing a photoresist on the antireflective coating;
exposing and developing the photoresist to form a pattern in the photoresist;
etching the antireflective coating through the pattern in the photoresist to form a pattern in the antireflective coating;
removing the photoresist; and
etching the metal layer through the pattern in the antireflective coating after removing the photoresist.

8. The method of claim 7 further comprising the step of:
controlling the step of etching the metal layer by adding a gas mixture containing carbon to an etching environment.

9. The method of claim 8, wherein the gas mixture comprises CHF₃ and a gas mixture selected from the group of BCl₃/Cl₂ and HBr/Cl₂ and gaseous HCL.

10. A method of forming a feature in a metal layer, the method comprising the steps of:
depositing a layer of antireflective material on a layer of metal;
forming a patterned layer of photoresist material on the layer of antireflective material;
forming a pattern in the layer of antireflective material through the patterned layer of photoresist material;
removing the layer of photoresist material; and
forming a feature in the metal layer through the pattern in the layer of antireflective material.

11. The method of claim 10 further comprising the step of:
controlling the formation of a carbon-based polymer during the step of forming a feature in the metal layer.

12. The method of claim 10 further comprising the step of:
controlling the step of forming a feature in the metal layer by adding a gas mixture containing carbon to an etching environment.

13. The method of claim 12, the gas mixture comprising CHF₃ and a gas mixture selected from the group of BCl₃/Cl₂ and HBr/Cl₂ and gaseous HCL.

14. A semiconductor device at a stage of manufacture comprising:
a substrate;
a metal layer disposed on the substrate; and
a layer of antireflective material having a pattern formed therein disposed on top of the metal layer, the pattern exposing at least a portion of a top surface of the metal layer, with no layer of material disposed on top of the antireflective material.

15. The device of claim 14 further comprising:
a pattern formed in the metal layer associated with the pattern in the layer of antireflective material.
